(19) United States
(12) Patent Application Publication
(10) Pub. No.: US 2012/0135609 A1
(43) Pub. Date: May 31, 2012

(54) Apparatus and Process for Atomic Layer Deposition

(75) Inventors: Joseph Yudovsky, Campbell, CA (US); Tatsuya Sato, San Jose, CA (US); Kenric Choi, San Jose, CA (US); Anh N. Nguyen, Milpitas, CA (US); Faruk Gungor, Santa Clara, CA (US)

(73) Assignee: Applied Materials, Inc., Santa Clara, CA (US)

(21) Appl. No.: 12/956,650

(22) Filed: Nov. 30, 2010

(51) Int. Cl. H01L 21/30; B67D 7/06

(52) U.S. Cl. 438/758; 222/129; 257/E21.211

(57) ABSTRACT

Provided are gas distribution plates (showerheads) for use in an apparatus configured to form a film during, for example, an atomic layer deposition (ALD) process. The gas distribution plate comprises a body defining a thickness and a peripheral edge and has a front surface for facing the substrate. The front surface has a central region with a plurality of openings configured to distribute process gases over the substrate and a focus ring with a sloped region. The focus ring is concentric to the central region such that the thickness at the focus ring is greater than the thickness at the central region.

### BACKGROUND

Embodiments of the invention generally relate to an apparatus and a method for depositing materials. More specifically, embodiments of the invention are directed to a gas distribution plate having a focus ring to form a more uniform film in an atomic layer deposition chamber.

In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 0.07 μm and aspect ratios of 10 or greater. Accordingly, conformal deposition of materials to form these devices is becoming increasingly important.

During an atomic layer deposition (ALD) process, reactant gases are sequentially introduced into a process chamber containing a substrate. Generally, a first reactant is introduced into a process chamber and is adsorbed onto the substrate surface. A second reactant is then introduced into the process chamber and reacts with the first reactant to form a deposited material. A purge step may be carried out between the delivery of each reactant gas to ensure that the only reactions that occur are on the substrate surface. The purge step may be a continuous purge with a carrier gas or a pulse purge between the delivery of the reactant gases.

The flow of process gases across the surface of a substrate affects the uniformity of the resultant film. Gas distribution plates have been designed to uniformly distribute gases but film uniformity remains a difficulty. Therefore, there is a need in the art for apparatuses and methods to more uniformly distribute process gases across the surface of a substrate to improve film uniformity.

### SUMMARY

Embodiments of the invention are directed to gas distribution plates to distribute process gases over a substrate surface. The gas distribution plates comprise a body defining a thickness and a peripheral edge. The body comprises a front surface for facing the substrate, the front surface having a central region having a plurality of openings configured to distribute process gases over the substrate and a focus ring having a sloped region. The focus ring is concentric to the central region such that the thickness at the focus ring is greater than the thickness at the central region.

In some embodiments, the focus ring and central region are shaped so that when the plate is adjacent a substrate there is a first distance between the central region and the substrate and a second distance between the focus ring and the substrate which is less than the first distance to evenly distribute the process gases. In detailed embodiments, the first distance is in the range of about 1.5 to about 6 times greater than the second distance. In specific embodiments, the first distance is in the range of about 2 to about 4 times greater than the second distance.

In one or more embodiments, the front surface has an overall concave shape defined by the central region surrounded by the sloped region of the focus ring. In specific embodiments, the sloped region is sloped at an angle in the range of about 5 to about 45 degrees.

The central region of some embodiments is substantially flat. The sloped region of one or more embodiments, extends to the peripheral edge. In various embodiments, the sloped region of the focus ring extends to an outer peripheral front face area.

In one or more embodiments, the gas distribution plate further comprises at least one channel forming a fluid connection between a gas inlet channel on a back surface of the body and the plurality of openings in the central region. In some embodiments, the gas distribution plate further comprises a central port extending through about a central axis of the substantially circular body, the central port configured to prevent mixing of a fluid passing through the central port from the process gases passing through the plurality of openings. In detailed embodiments, the central port is in fluid communication with one or more of a vacuum system and a precursor source.

Additional embodiments of the invention are directed to processing chamber comprising the gas distribution plate described. In specific embodiments the processing chamber is an atomic layer deposition chamber.

Further embodiments of the invention are directed to methods of processing a substrate. A substrate having an edge region surrounding an inner region is disposed in a process chamber adjacent a gas distribution plate defining a reaction region between the substrate and the distribution plate. The reaction region is smaller at the edge region than at the inner region. At least a first process gas is flowed through the plurality of openings in the front face of the gas distribution plate to the substrate.

In detailed embodiments, the distribution plate comprises a body defining a thickness and a peripheral edge. The body comprises a front surface for facing the substrate, the front surface having a central region having a plurality of openings configured to distribute process gases over the substrate and a focus ring having a sloped region. The focus ring is concentric to the central region such that the thickness at the focus ring is greater than the thickness at the central region.

In some embodiments, the gas distribution plate further comprises a central port extending through about a central axis of the substantially circular central region. In detailed embodiments, the methods further comprise flowing at least a second process gas through the central port to the substrate. In specific embodiments, at least a partial vacuum is applied to a region between the substrate and the central region of the gas distribution plate through the central port. One or more embodiments of the methods further comprise alternately flowing the first process gas through the plurality of openings and the at least one second process gas through the central port.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic view of a process chamber according to one or more embodiments of the invention;

FIGS. 2 and 3 show expanded schematic views of channels in a gas distribution plate in accordance with one or more embodiments of the invention;

FIG. 4 shows a partial schematic view of a process chamber with a gas distribution plate with a focus ring in accordance with one or more embodiments of the invention; and

FIGS. 5 and 6 show schematic views of gas distribution plates with focus rings in accordance with one or more embodiments of the invention.

### DETAILED DESCRIPTION

Embodiments of the invention are directed to gas distribution plates, also referred to as showerheads, which provide improved film uniformity by improving gas flow distribution. Specific embodiments of the invention are directed to atomic layer deposition apparatuses (also called cyclical deposition) incorporating a gas distribution plate having a shape configured to improve the gas flow distribution.

As used in this specification and the appended claims, the term “gas distribution plate” and “showerhead” are used interchangeably. A “gas distribution plate” is a component of the gas distribution system and is commonly referred to as a “showerhead” due to the fact that it has a hole pattern which is often reminiscent of a shower head.

In one or more embodiments, two precursors can flow into a process chamber through two individual gas supply passages. One of these precursors will be distributed uniformly (e.g., HfCl₄) and the other can be supplied through a single point of entry (usually oxidizers like water or ozone).

A showerhead with focus ring can be used for the HfCl₄ distribution. A focus ring provides better edge coverage by reducing the process gap between the showerhead and the heater surface. In some embodiments, a blocker plate and baffle could also be included to further improve gas flow uniformity. An oxidizer could be introduced through a single or multiple jets directed toward the wafer or across it. A single inject could be positioned in the center of the chamber or any other location as desired.

A showerhead with variable spacing could be used for ALD applications. The variable spacing will affect the precursor residence time, effectiveness of purging of the byproducts and the reactants and used for thickness tuning. An additional central vacuum port can be positioned in the center of the showerhead. This port provides effective pumping f the central spot of the water, which is a stagnation zone for an existing peripheral axi-symmetric pumping. The central vacuum port could be used for injection of a precursor in case when pumping step does not coincide with a precursor pulse. A co-axial configuration of the central pumping port and central inject could be utilized by providing pumping tube inside of the central inject or vice versa.

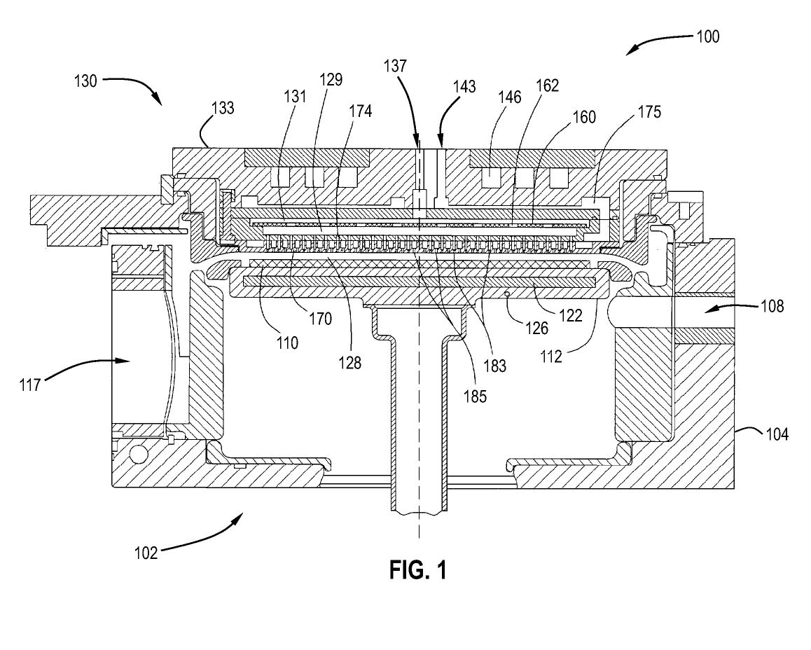

FIG. 1 shows a schematic, cross-sectional view of one or more embodiments of a process chamber 100 (e.g., ALD chamber) for performing a film deposition. The process chamber 100 comprises a chamber body 102 and a gas distribution system 130. The chamber body 102 houses a substrate support 112 that supports a substrate 110 in the chamber 100. The substrate support 112 comprises an embedded heater element 122. A temperature sensor 126 (e.g., a thermocouple) is embedded in the substrate support 112 to monitor the temperature of the substrate support 112. Alternatively, the substrate 110 may be heated using a source of radiant heat (not shown), such as quartz lamps and the like. Further, the chamber body 102 comprises an opening 108 in a sidewall 104 providing access, for example, for a robot to deliver and retrieve the substrate 110, as well as an exhaust port 117.

The gas distribution system 130 generally comprises a mounting plate 133, a showerhead 170, and a blocker plate 160 and provides at least two separate paths for gaseous compounds into a reaction region 128 between the showerhead 170 and the substrate support 112. In the depicted embodiment, the gas distribution system 130 also serves as a lid of the process chamber 100. However, in other embodiments, the gas distribution system 130 may be a portion of a lid assembly of the chamber 100. The mounting plate 133 comprises a channel 137 and a channel 143, as well as a plurality of channels 146 that are formed to control the temperature of the gaseous compounds (e.g., by providing either a cooling or heating fluid into the channels). Such control is used to prevent decomposing or condensation of the compounds. Each of the channels 137, 143 provides a separate path for a gaseous compound within the gas distribution system 130.

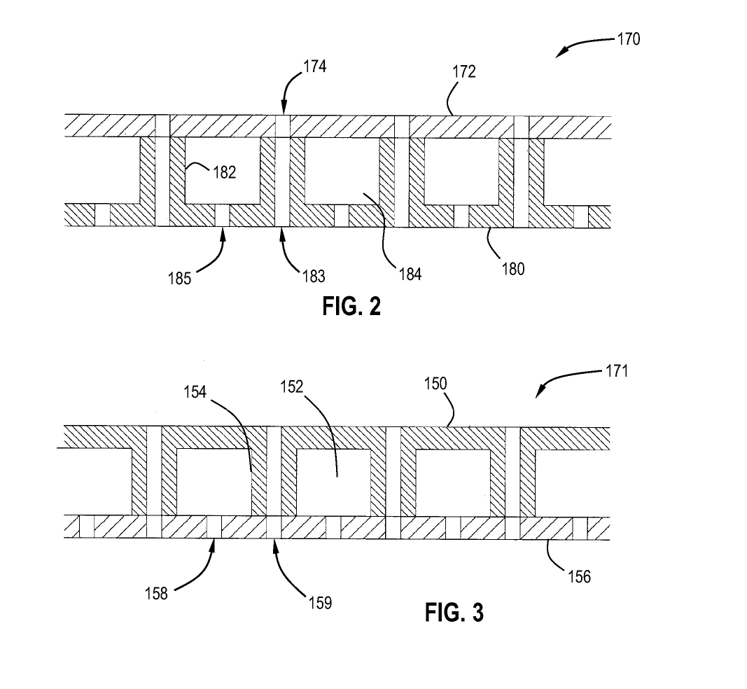

FIG. 2 is a schematic, partial cross-sectional view of one embodiment of the showerhead 170. The showerhead 170 comprises a plate 172 that is coupled to a base 180. The plate 172 has a plurality of openings 174, while the base 180 comprises a plurality of columns 182 and a plurality of grooves 184. The columns 182 and grooves 184 comprise openings 183 and 185, respectively. The plate 172 and base 180 are coupled such, that the openings 183 in the base align with the openings 174 in the plate to form a path for a first gaseous compound through the showerhead 170. The grooves 184 are in fluid communication with one another and, together, facilitate a separate path for a second gaseous compound into the reaction region 128 through the openings 185. In an alternative embodiment, shown in FIG. 3, the showerhead 171 comprises the plate 150 having the grooves 152 and columns 154, and a base 156 comprising a plurality of openings 158 and 159. In either embodiment, contacting surfaces of the plate and base may be brazed together to prevent mixing of the gaseous compounds within the showerhead.

Referring again to FIG. 1, each of the channels 137 and 143 is coupled to a source of the respective gaseous compound. Further, the channel 137 directs the first gaseous compound into a volume 131, while the channel 143 is coupled to a plenum 175 that provides a path for the second gaseous compound to the grooves 184 (shown in FIG. 2). The blocker plate 160 comprises a plurality of openings 162 that facilitate fluid communication between the volume 131, plenum 129, and a plurality of openings 174 that disperse the first gaseous compound into the reaction region 128. As such, the gas distribution system 130 provides separate paths for the gaseous compounds delivered to the channels 137 and 143.

In some embodiments, the blocker plate 160 and the showerhead 170 are electrically isolated from one another, the mounting plate 133, and chamber body 102 using insulators (not shown) formed of, for example, quartz, ceramic, and the like. The insulators are generally disposed between the contacting surfaces in annular peripheral regions thereof to facilitate electrical biasing of these components and, as such, enable plasma enhanced cyclical deposition techniques, e.g., plasma enhanced ALD (PEALD) processing.

In one exemplary embodiment, a power source may be coupled, e.g., through a matching network (both not shown), to the blocker plate 160 when the showerhead 170 and chamber body 102 are coupled to a ground terminal. The power source may be one or more of a radio-frequency (RF) or direct current (DC) power source that energizes the gaseous compound in the plenum 129 to form a plasma. Alternatively, the power source may be coupled to the showerhead 170 when the substrate support 112 and chamber body 102 are coupled to the ground terminal. In this embodiment, the gaseous compounds may be energized to form a plasma in the reaction region 128. As such, the plasma may be selectively formed either between the blocker plate 160 and showerhead 170, or between the showerhead 170 and substrate support 112.

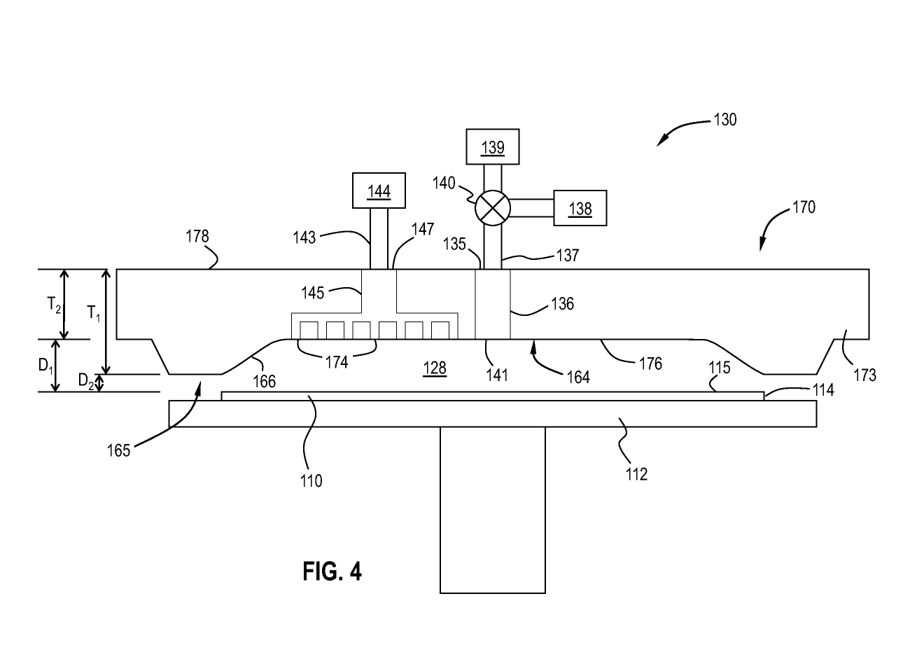

FIG. 4 shows a gas distribution system 130 according to one or more embodiments of the invention. The gas distribution system 130 includes a gas distribution plate, also called a showerhead 170, which can distribute process gases over the substrate 110 surface. The showerhead 170 (gas distribution plate) comprises a body 173 defining a thickness and a peripheral edge 177. The body 173 comprises a front surface 176 for facing the substrate 110 and a back surface 178 opposite the front surface 176. The front surface 176 has a central region 164 having a plurality of openings 174 configured to distribute process gases over the substrate 110. The body 173 also has a focus ring 165 having a sloped region 166. The focus ring 165 is concentric to the central region 164 such that the thickness T₁ at the focus ring 165 is greater than the thickness T₂ at the central region 164.

In detailed embodiments, the focus ring 165 and central region 164 are shaped so that when the gas distribution plate (showerhead 170) is adjacent a substrate 110 there is a first distance D₁ between the central region 164 and the substrate 110 and a second distance D₂ between the focus ring 165 and the substrate 110 which is less than the first distance D₁ to evenly distribute the process gases. The first distance D₁ is in the range of about 1.5 to about 6 times greater than the second distance. In specific embodiments, the first distance D₁ is in the range of about 2 to about 4 times greater than the second distance D₂.

As can be seen in FIGS. 4-6, the front surface 176 of the showerhead 170 has an overall concave shape defined by the central region 164 surrounded by the sloped region 166 of the focus ring 165. The sloped region 166 is sloped at an angle Θ in the range of about 5 to about 75 degrees. In various embodiments, the sloped region 166 is sloped at an angle in the range of about 20 to about 75 degrees, or in the range of about 5 to about 45 degrees. In detailed embodiments, the sloped region 166 is sloped at an angle about 30°, or about 45° or about 60°. The length of the sloped region 166 can vary and is related to the angle of the sloped region and the thickness of the focus ring.

In detailed embodiments the central region 164 is substantially flat. As used in this specification and the appended claims, the term “substantially flat” means that the surface has deviations from flatness that is less than about 100 μm, or that when the central region is placed an operable distance from a substrate, there is less than about a 10% deviation, or less than about a 5% deviation, in the distance to the substrate surface. In specific embodiments, the central region 164 is slightly concave.

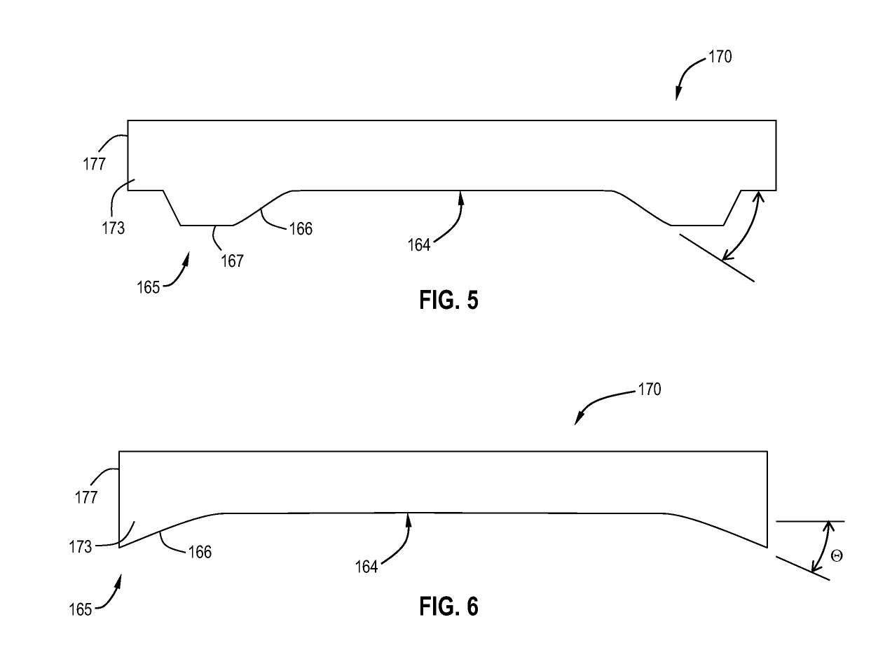

FIG. 5 shows an embodiment of the gas distribution plate (showerhead 170) in which the sloped region 166 of the focus ring 165 extends to an outer peripheral front face 167 area. The embodiment shown has a decrease in the thickness of the showerhead 170 outside the focus ring 165 leading to the peripheral edge 177. Said differently, the outer peripheral front face 167 of the focus ring 165 does not extend to the peripheral edge 177 of the showerhead 170. This is merely illustrative and should not be taken as limiting the scope of the invention. In some embodiments, the peripheral front face 167 of the focus ring 165 extends to the peripheral edge 177 of the showerhead 170. FIG. 6 shows another embodiment of the gas distribution plate (showerhead 170) in which the sloped region 166 extends to the peripheral edge 177. The focus ring 165 of this embodiment does not have an outer peripheral front face 167 area.

The size of the central region 164 of the showerhead 170, and the showerhead 170 itself, can vary depending on the size of the substrate 110. For example, as shown in FIG. 4, the substrate extends outside the central region 164 and sloped region 166 of the showerhead 170 so that the edge region 114 of the substrate 110 is approximately adjacent the outer peripheral front face 167 of the focus ring 165. This is merely illustrative and it should be understood that the size of the showerhead 170 and substrate 110 can vary. In some embodiments, the edge region 114 of the substrate 110 extends to a point where it would be adjacent the sloped region 166 of the focus ring 165. In specific embodiments, the edge region 114 of the substrate 110 remains below the central region 164 of the showerhead 170 so that the entire focus ring 165 is outside the edge region 114 of the substrate 110 during processing.

Referring again to FIG. 4, some embodiments of the gas distribution system 130 further comprise at least one channel 145 which forms a fluid connection between a gas inlet channel 147 on the back surface 178 of the body 173 and the plurality of openings 174 in the front surface 176. FIG. 4 shows a simplified view of this concept with a precursor source 144 in flow communication with a channel 143 which connects to the back surface 178 of the body 173. The channel 143 from the precursor source 144 is shown smaller than the channel 145 inside the showerhead 170. This is merely for illustrative purposes and it is contemplated that these channels can be same size or different sizes. In some embodiments, the precursor source 144 is in flow communication with a channel 143 which leads to a plenum 175 (as shown in FIG. 1) which then leads to the at least one channel 145 within the showerhead 170.

In specific embodiments, the plurality of openings 174 are located in the central region 164 of the front surface 176. In these embodiments, the gas flowing from the plurality of openings 174 is directed generally perpendicular to the surface of the substrate 110. It is also contemplated that the plurality of openings 174 in the front surface 176 may extend along the sloped region 166 of the focus ring and even potentially to a peripheral front face 167 area. Showerheads 170 with openings 174 on the focus ring 165 present a more complicated gas flow pattern which, depending on various factors including flow rate and pressure, may provide a more even distribution of gases across the surface of the substrate 110.

The embodiment shown in FIG. 4 includes a central port 136 extending through the body 173. The central port 136 extends through a region at or near the central axis of the body 173. The central port 136 is in fluid communication with a second precursor source 138 or a vacuum source 139, and allows for the introduction of the second precursor or vacuum to the reaction region 128 while preventing mixing of the fluid passing through the central port 136 with the process gas 144 passing through the channels 145 and out the plurality of openings 174. The central port 136 shown in FIG. 4 has a single opening 141 at the front surface 176 of the showerhead 170, but is should be understood that this central port 136 can also have multiple openings. In some embodiments, the central port contains two discreet pathways, one for vacuum and the other for a precursor or oxidizer gas. The discreet pathways can be positioned side-by-side or can be coaxial with a pumping tube inside of a central inject, or vice versa.

The central port 136 or the plurality of openings 174 can also be used to inject a remotely generated plasma into the reaction region 128. In embodiments of this sort, either of the first precursor source 144 or second precursor source 138 could generate a plasma outside of the reaction region 128 and then introduce the plasma through the showerhead 170.

A channel 137 is connected to the central port 136 through a gas inlet channel 135. The channel 137 and gas inlet channel 135 are shown with different diameters but it should be understood that these sizes of these channels can be the same or different depending on the specific system configuration. The channel 137 can be connected to at least one precursor source 138 or vacuum source 139. In the embodiment shown in FIG. 4, the channel is connected through a metering/switching device 140 to both a second precursor source 138 and a vacuum source 139.

The showerhead 170 may be formed from a variety of materials including a metal or another electrically conductive material. In detailed embodiments, the showerhead 170 is formed from quartz or a metal, such as aluminum, steel, stainless steel, iron, nickel, chromium, aluminum nitride, an alloy thereof or combinations thereof.

The plurality of openings 174 in showerhead 300 may be arranged in various configurations and can have differing sizes and numbers. In detailed embodiments, each of the plurality of openings 174 have a diameter within the range from about 0.10 mm to about 1.00 mm. In specific embodiments, each of the plurality of openings 174 has a diameter in the range of about 0.20 mm to about 0.80 mm. In more specific embodiments, each of the plurality of openings has a diameter in the range of about 0.40 mm to about 0.60 mm. The showerhead 170 of detailed embodiments has at least about 100 holes. In specific embodiments, the showerhead 170 has at least about 1000 openings 174 or at least about 1,500 openings 174. The showerhead 170 of some embodiments may have as many as 6,000 openings or 10,000 openings depending on size, distribution pattern of the openings 310, size of the substrate 110 to be processed and the desired exposure rate. The openings 174 may have a varying or consistent geometry from hole to hole. In a specific embodiment, the showerhead 170 is constructed from metal (e.g., aluminum or stainless steel) and has about 1,500 holes that are formed with a diameter of about 0.50 mm.

Additional embodiments of the invention are directed to process chambers 100 comprising the gas distribution plate (showerhead 170) described. In some embodiments, the process chamber 100 is a chemical vapor deposition chamber. The process chamber 100 of specific embodiments is an atomic layer deposition chamber.

Further embodiments of the invention are directed to methods of processing a substrate. A substrate 110 having an edge region 114 surrounding an inner region 115 is disposed in a process chamber 100 adjacent a gas distribution plate (showerhead 170). A reaction region 128 is defined as the region between the substrate 110 and the gas distribution plate (showerhead 170). The reaction region 128 is smaller a the edge region 114 than at the inner region 115. Stated differently, the size of the gap between the edge region 114 of the substrate and the showerhead 170 is smaller than the size of the gap between the inner region 115 and the showerhead 170. At least a first process gas from a first precursor source 144 is flowed through the plurality of openings 174 in the front surface 176 of the gas distribution plate (showerhead 170) to the substrate 110.

Some embodiments further comprise flowing at least a second process gas from a second precursor source 138 through the central port 136 in the showerhead 170 to the substrate 110. One or more embodiments further comprise applying at least a partial vacuum from a vacuum source 139 to the reaction region 128 between the substrate 110 and the central region 164 of the gas distribution plate (showerhead 170) through the central port 136 in the showerhead 170.

In detailed embodiments, a first process gas from a first precursor source 144 is flowed through a plurality of openings 174 in the showerhead 170 to the substrate 110. After the first process gas has reacted with the substrate 110, a purge gas or vacuum can be employed to remove any unreacted first process gas or reaction byproducts. A second process gas is then flowed from a second precursor source 138 through the central port 136 to the substrate 110. Each of these process gas reactions can be repeated before flowing the other process gas to the substrate and the entire process can be repeated multiple times. A third process gas (not shown) can be flowed through the showerhead 170 through the same channels 145 and openings 174 or through a different channel and openings which are segregated from the first set. This allows for multiple atomic layer deposition reactions to be performed in the same chamber with the same showerhead 170. Additionally, the third process gas can be connected to the metering/switching device 140 and allowed to flow through the central port 136 to the substrate 110.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

1. A gas distribution plate that distributes process gases over a substrate surface, the gas distribution plate comprising a body defining a thickness and a peripheral edge, the body comprising a front surface that faces the substrate, the front surface having a central region having a plurality of openings that distribute process gases over the substrate and a focus ring having a sloped region, the focus ring concentric to the central region such that the thickness at the focus ring is greater than the thickness at the central region.

2. The gas distribution plate of claim 1, wherein the focus ring and central region are shaped so that when the plate is adjacent a substrate there is a first distance between the central region and the substrate and a second distance between the focus ring and the substrate which is less than the first distance to evenly distribute the process gases.

3. The gas distribution plate of claim 2, wherein the first distance is in the range of about 1.5 to about 6 times greater than the second distance.

4. The gas distribution plate of claim 2, wherein the first distance is in the range of about 2 to about 4 times greater than the second distance.

5. The gas distribution plate of claim 1, wherein the front surface has an overall concave shape defined by the central region surrounded by the sloped region of the focus ring.

6. The gas distribution plate of claim 5, wherein the sloped region is sloped at an angle in the range of about 5 to about 45 degrees.

7. The gas distribution plate of claim 1, wherein the central region is substantially flat.

8. The gas distribution plate of claim 1, wherein the sloped region extends to the peripheral edge.

9. The gas distribution plate of claim 1, where in the sloped region of the focus ring extends to an outer peripheral front face area.

10. The gas distribution plate of claim 1, further comprising at least one channel forming a fluid connection between a gas inlet channel on a back surface of the body and the plurality of openings in the central region.

11. The gas distribution plate of claim 1, further comprising a central port extending through about a central axis of the substantially circular body, the central port preventing mixing of a fluid passing through the central port with the process gases passing through the plurality of openings.

12. The gas distribution plate of claim 11, wherein the central port is in fluid communication with one or more of a vacuum system and a precursor source.

13. A processing chamber comprising the gas distribution plate of claim 1.

14. The processing chamber of claim 13, wherein the processing chamber is an atomic layer deposition chamber.

15. A method of processing a substrate comprising:
disposing the substrate having an edge region surrounding an inner region in a process chamber adjacent a gas distribution plate defining a reaction region between the substrate and the gas distribution plate, the reaction region being smaller at an edge region than at an inner region; and
flowing at least a first process gas through a plurality of openings in a front face of the gas distribution plate to the substrate.

16. The method of claim 15, wherein the gas distribution plate comprises a body having the front face, a thickness and a peripheral edge, the front face facing the substrate, the front face having a central region including the plurality of openings that distribute process gases over the substrate and a focus ring having a sloped region, the focus ring concentric to the central region such that the thickness at the focus ring is greater than the thickness at the central region.

17. The method of claim 15, wherein the gas distribution plate further comprises a central port extending through about a central axis of the substantially circular central region.

18. The method of claim 17, further comprising flowing at least a second process gas through the central port to the substrate.

19. The method of claim 17, further comprising applying at least a partial vacuum to a region between the substrate and the central region of the gas distribution plate through the central port.

20. The method of claim 18, further comprising alternately flowing the first process gas through the plurality of openings and the at least one second process gas through the central port.
